(19) United States
(12) Patent Application Publication
(10) Pub. No.: US 2018/0310409 A1
(43) Pub. Date: Oct. 25, 2018

(54) STACKED OUTPUT STRUCTURE OF CAPACITIVE POWER SUPPLY FOR WELDING EQUIPMENT

(71) Applicant: BOSJOB COMPANY LTD., Jiangmen City (CN)

(72) Inventors: Liang-huan WENG, Jiangmen City (CN); Min-hsiang WENG, Jiangmen City (CN)

(73) Assignee: BOSJOB COMPANY LTD.

(21) Appl. No.: 15/841,324

(22) Filed: Dec. 14, 2017

(30) Foreign Application Priority Data
Apr. 21, 2017 (CN) 201710267582.3
Apr. 21, 2017 (CN) 201720431042.X

(51) Int. Cl. H05K 1/18; H05K 1/14; H05K 1/02; B23K 9/10

(52) U.S. Cl. CPC H05K 1/18; H05K 1/144; H05K 1/0263; B23K 9/1006; H05K 2201/09227; H05K 2201/10015; H05K 2201/10901; H05K 2201/10522; H05K 2201/10189; H05K 2201/10303; H05K 2201/10333; H05K 2201/10651; H05K 2201/10166

(57) ABSTRACT

A stacked output structure of a capacitive power supply for welding equipment, having a plurality of capacitors to be connected in parallel, two electrodes of each capacitor are respectively provided with a pin including a long pin and a short pin; at least two PCB bus plates placed in stack are provided above the capacitor is provided. A lower PCB bus plate is connected with the short pin; and a pass-through hole is provided, at a position corresponds to the long pin, on the lower PCB bus plate. The long pin passes through the pass-through hole in the lower PCB bus plate and is connected with an upper PCB bus plate. There is a gap between the long pin and an inner wall of the pass-through hole.

### FIELD OF INVENTION

The present disclosure relates to a power supply of welding equipment, and in particular, to a stacked output structure of a capacitive power supply for welding equipment.

### BACKGROUND OF INVENTION

There are several conventional power supplies available for welding equipment, which are simply classified as a transformer type, an inverter type, a storage capacitor type, etc. The storage capacitor power supply has the advantages of short welding time, high energy density in unit time, etc., and is widely applied in welding equipment, such as an energy storage type stud welding machine, a spot welding machine, a cold patching machine, etc.

A traditional capacitive power supply adopts a screw type large electrolytic capacitor which conducts large-current discharge cooperating with a copper bar, an aluminum bar or a cable, with a peak current at the moment of discharging up to thousands or even tens of thousands of amperes. The disadvantage of the traditional capacitive power supply are as follows: the greater the capacity of the electrolytic capacitor is, the larger the impedance and the inductive reactance in the capacitor; the poorer high-frequency dynamic response resulting in a reduced discharging speed, so that the energy density in unit time cannot be obviously improved when discharging.

An improved method to the above includes the large electrolytic capacitor being replaced by a plurality of parallelly connected small capacitors. The small capacitor has a low impedance and inductive reactance and the instantaneous discharge performance is improved. However, more parallelly connected capacitors mean that more contacts and a longer power bus are needed for conduction. And since there are more parallelly connected small capacitors, and positive electrodes and negative electrodes thereof must be insulated, so that the width of the power bus is limited, and the whole loop is lengthened and the internal impedance is increased correspondingly. This is very unfavorable for the applications requiring high instantaneous current output.

FIG. 1 is an arrangement for power buses when large traditional electrolytic capacitors are used in parallel. Since the capacitor 1 has a positive and a negative pole, to ensure that no short circuit occurs between a positive power bus 2 and a negative power bus 3, the power bus needs to be cut in shape; and the power buses are usually made into copper bars or aluminum bars. FIG. 2 is an arrangement for power buses when a plurality of small electrolytic capacitors are used in parallel. Since the capacitor 1 has a positive and a negative pole, to ensure that no short circuit occurs between the positive power bus 2 and the negative power bus 3, the power bus needs to be cut in shape which presents a “U” or “E” shape as shown. The power buses are usually made into copper bars or aluminum bar. Whether it is a parallel arrangement of large electrolytic capacitors or a parallel application of small electrolytic capacitors, the negative electrodes and positive electrodes must be insulated from one another, which results in a reduced power bus area and a reduced cross-sectional area. From the top view, no matter the area of the negative electrode power bus or of the positive electrode power bus, the area is less than 50% of the whole plane (the wasted insulation space between the negative electrode and the positive electrode must be deducted), and the output ends face north and south, respectively. However, the arrangement of output ends of the equipment usually must ensure that positive and negative outputs are directed towards the same side. Thus, cables or additional power buses have to be used for bridge connection to connect and introduce the positive and negative output ends to the output ends of the equipment, which, however, increases the output impedance.

### SUMMARY

In order to address the above technical problems, embodiments of the present disclosure provide a stacked output structure of a capacitive power supply for welding equipment.

One of the technical solutions according to and embodiment of the present disclosure includes: a stacked output structure of a capacitive power supply for welding equipment, having a plurality of capacitors to be connected in parallel, two electrodes of each capacitor are respectively provided with a pin upwards, wherein: the two pins of each of the capacitors includes a long pin and a short pin, a group of pins with the same height being provided with the same polarity; at least two PCB (printed circuit board) bus plates placed in stack are provided above the capacitor, wherein: a lower PCB bus plate is connected with the short pin; and a pass-through hole is provided, at a position corresponding to the long pin, on the lower PCB bus plate; and the long pin passes through the pass-through hole in the lower PCB bus plate and is connected with an upper PCB bus plate; and there is a gap between the long pin and an inner wall of the pass-through hole.

As a further improvement to the above technical solution, a conductive bus layer is provided on a surface of a PCB bus plate.

As a further improvement to the above technical solution, at least one conductive bus layer is provided within a PCB bus plate.

As a further improvement to the above technical solution, bus layers on the same PCB bus plate are provided for the same polarity; and the pins are connected with the bus layers of the PCB bus plate.

As a further improvement to the above technical solution, an insulation layer for protecting a bus layer is provided on a surface of the PCB bus plate.

As a further improvement to the above technical solution, an insulation layer for separating each bus layer is provided within the PCB bus plate.

As a further improvement to the above technical solution, a PCB control board is provided above the stack of PCB bus plates; and pins for power terminals of the PCB control board are respectively connected with the PCB bus plates with different polarities.

Another technical solution provided by embodiments of the present disclosure includes: a stacked output structure of the capacitive power supply for welding equipment, having a plurality of capacitors to be connected in parallel, and two electrodes of each capacitor are respectively provided with a pin upwards, wherein: the two pins of each of the capacitors includes a long pin and a short pin, a group of pins with the same height being provided with the same polarity; a PCB bus plate is provided above the capacitor; at least two bus layers are provided on and/or within the PCB bus plate; and the bus layers are separated by an insulation layer; a plurality of hole slots leading to respective bus layers are formed on one side of the PCB bus plate facing the capacitors; and the short pin of each capacitor is connected with a lower bus layer by means of a hole slot; and the long pin of each capacitor is connected with an upper bus layer by means of a hole slot.

Advantages of the embodiments of the present disclosure include the following. Compared with the prior art, the stacked output structure of the capacitive power supply provided by the present disclosure can greatly reduce the impedance and inductive reactance when outputting the power, and improve the output ratio of the capacitive power supply. Besides, the stacked output structure allows a more flexible arrangement and can be conveniently connected with other components, such as the control board, etc. Thus, the stacked output structure is practical and convenient and has great market competitiveness.

### BRIEF DESCRIPTION OF THE DRAWINGS

The disclosure is further described in cooperation of drawings and embodiments, as follows.

FIG.1 is a design of an arrangement for the power buses when large traditional electrolytic capacitors are used in parallel.

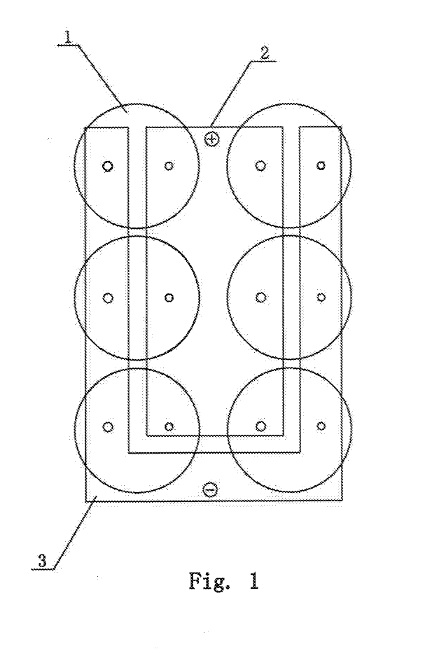

FIG. 2 is a design of an arrangement for the power buses when a plurality of small electrolytic capacitors are used in parallel.

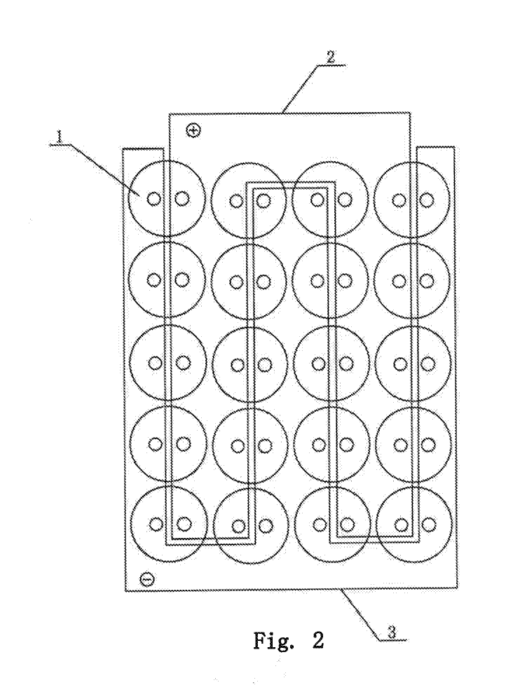

FIG. 3 is a schematic structural diagram of a stacked output structure of a capacitive power supply according to an embodiment of the present disclosure.

FIG. 4 is a schematic structural diagram of a MOSFET electronic switching device integrated on a PCB bus plate.

FIG. 5 is a schematic structural diagram of interfaces on the positive PCB bus plate and the negative PCB bus plate, for connecting the PCB control board.

FIG. 6A is a schematic structural diagram of a stacked output structure of a capacitive power supply according to an embodiment of the present disclosure.

FIG. 6B is a schematic structural diagram of a stacked output structure of a capacitive power supply according to another embodiment of the present disclosure.

### DETAILED DESCRIPTION

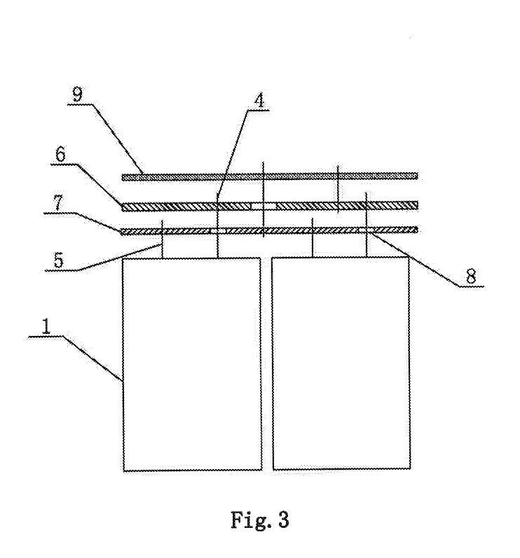

Referring to FIG. 3, an embodiment of the present disclosure provides a stacked output structure of a capacitive power supply with two PCB (printed circuit board) bus plates. The embodiment includes a plurality of capacitors 1 to be connected in parallel; two electrodes of each capacitor are respectively provided with a pin upwards, and each capacitor has two pins, including a long pin 4 and a short pin 5. In the embodiment, the long pin 4 is connected with a positive electrode of the capacitor 1; and the short pin 5 is connected with a negative electrode of the capacitor 1. Two PCB bus plates in stack are arranged above the capacitor 1, wherein a lower negative PCB bus plate 7 (as shown in cross sectional view) is connected with the short pin 5 to converge the current from the negative electrode; a pass-through hole 8 is arranged, at a position corresponds to the long pin 4, on the negative PCB bus plate 7; the long pin 4 is connected with an upper positive PCB bus plate 6 located above the lower negative PCB bus plate 7 through the pass-through hole 8 of the negative PCB bus plate 7 to converge the current from the positive electrode. When the long pin 4 passes through the pass-through hole 8, there is an insulation gap left between the long pin and the inner wall of the pass-through hole 8.

Conductive bus layer(s) are generally arranged on either surface or both surfaces of each PCB bus plate; and the pins are connected with the bus layers of the PCB bus plate. Further, at least one bus layer can be provided within the PCB bus plate, the at least one bus layer are separated by insulation layers. The total surface area of the bus layers can be accumulated and increased in multiples by providing a plurality of bus layers on and/or within the PCB plate. From the point of view of a cross sectional area of the bus bar, the total cross sectional area of all the bus layers of the PCB power bus may be not greater than that of the traditional aluminum bar and copper bar. However, since the instantaneous dl/dt (current change rate) is high in a capacitor instantaneous discharge equipment, a maximum electromotive force can be induced by the center of the conductor due to the skin effect (also called skin-collecting effect), so that the current tends to be forced to get closer to the outer surface of the conductor, therefore, the greater the surface area of the conductor is, the better conducting effect will be obtained. Therefore, the converging ability can be greatly improved by using the PCB plate with the plurality of bus layers.

Further, an insulation layer for protecting a bus layer can also be arranged on the surface of the PCB bus plate.

In addition, in an embodiment, adopting the stacked PCB bus plates facilitates the adding of a control board. As shown in FIG. 3, a PCB control board 9 is arranged above the upper positive PCB bus plate 6, by laminating above the latter, to save space. Meanwhile, the PCB control board 9 can be directly connected with the positive PCB bus plate 6 and the negative PCB bus plate 7 to deliver or take power, which is very convenient.

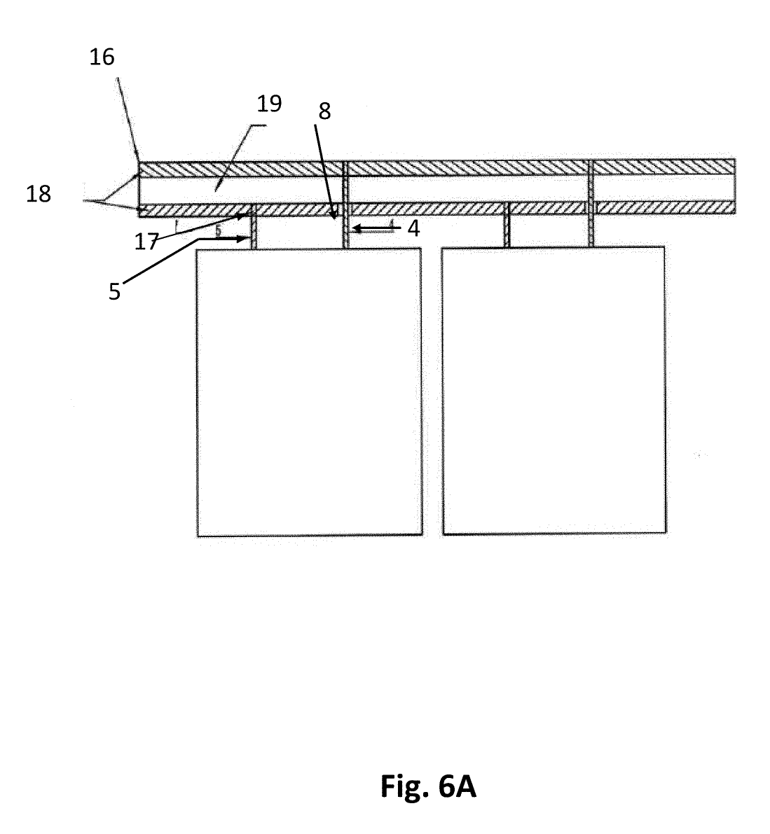

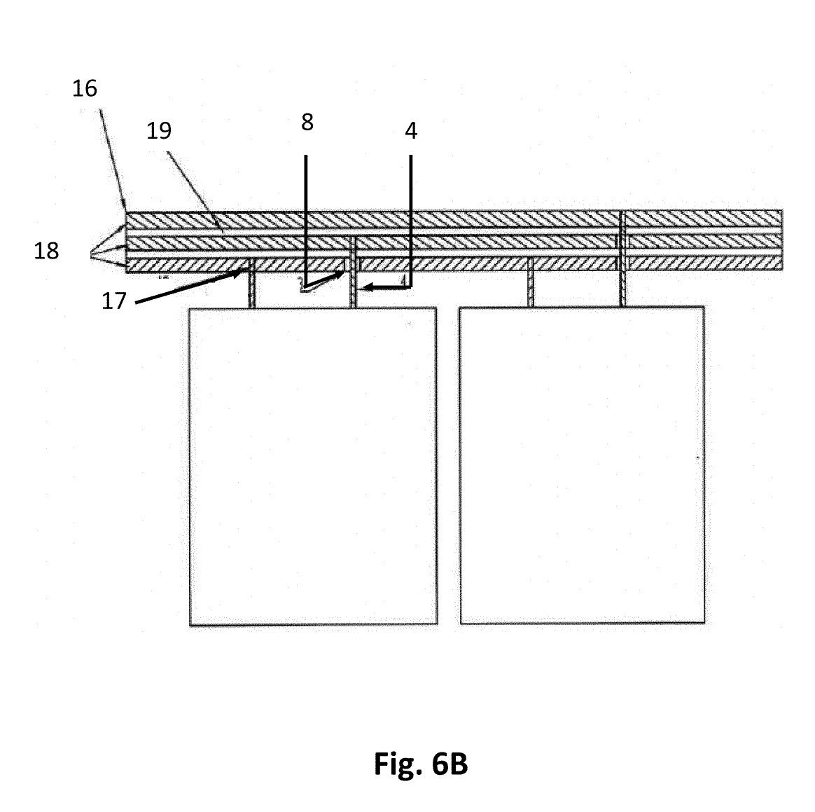

As shown in FIGS. 6A and 6B, the structure of another embodiment according to the present disclosure is largely the same as that of the first embodiment except that in the second embodiment, only one PCB bus plate 16 is provided; at least two separated bus layers 18 are arranged on and/or within the PCB bus plate; the bus layers are separated by insulation layers 19; a plurality of hole slots 17 leading to respective bus layers are formed on one side of the PCB bus plate facing the capacitor; and the short pin 5 of the capacitor is connected with a lower bus layer by means of the hole slot, and the long pin 4 of the capacitor passes through, such as the pass-through hole 8 mentioned above, and is connected with an upper bus layer by means of the hole slot mentioned above. This embodiment features that the afore-mentioned plurality of PCB bus plates arranged apart are now replaced by a single high-ounce (multi-layers of conductive copper foils within a PCB) PCB bus plate, which is applicable in smaller current and smaller volume.

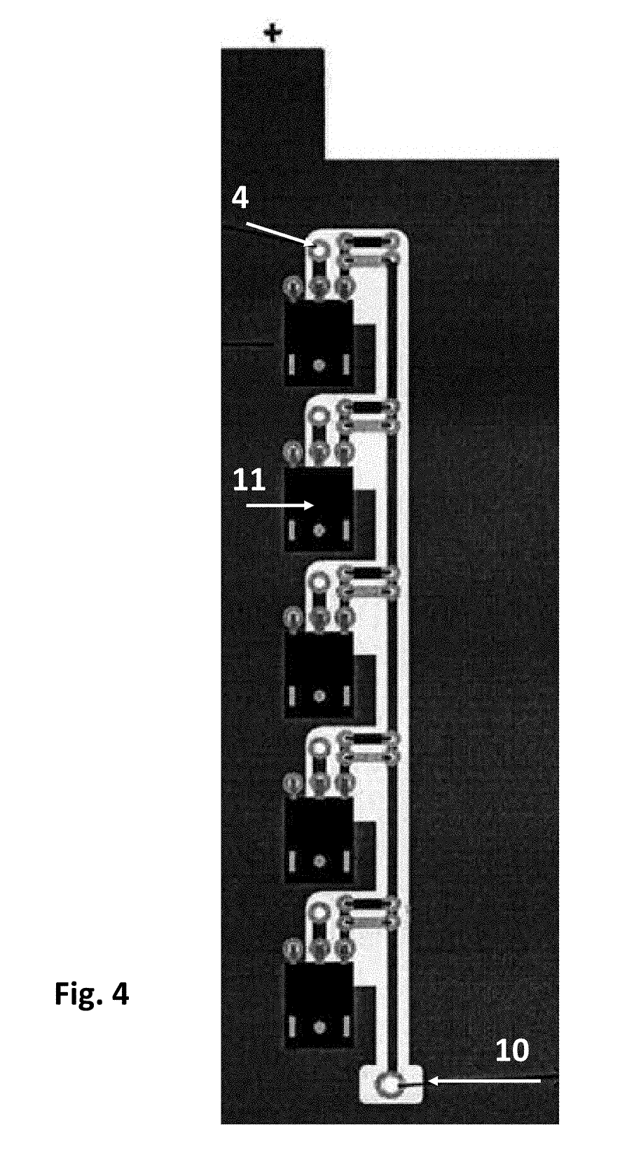

In a further embodiment of the present disclosure, the stacked output structure of the present disclosure also includes an MOSFET (metal oxide semiconductor field effect transistor) electronic switching device integrated on a PCB bus plate and a corresponding MOSFET drive circuit on the PCB bus plate. As shown in Fig.4, a drive signal input port 10 is provided at the lower end of the positive PCB bus plate 6, and the positive PCB bus plate 6 is arranged with a plurality of MOSFET electronic switching devices 11, a copper foil cabling on the positive PCB bus plate 6 keeps the MOSFET drive circuit insulated from a power output circuit. This embodiment features that the integrated MOSFET drive circuit can simultaneously drive more than one MOSFET. As an electronic switching device, MOSFET has the advantages of small size, small conduction voltage drop, small conduction resistance, simple drive circuit and low energy consumption. With the evolution of semiconductor technology, high-power POWER MOSFET has a very strong instantaneous current resistance, and after the actual verification, the use of multiple MOSFETs to replace the large-scale SCR (silicon controlled rectifier) of the prior art effectively reduce the volume and cost. Stacked structure power buses made of metal foils in the prior art cannot integrate various electronic devices (especially electronic switching devices) on the power buses. According to an embodiment of the present disclosure, an IGBT (insulated gate bipolar transistor) can also be used as an electronic switching device.

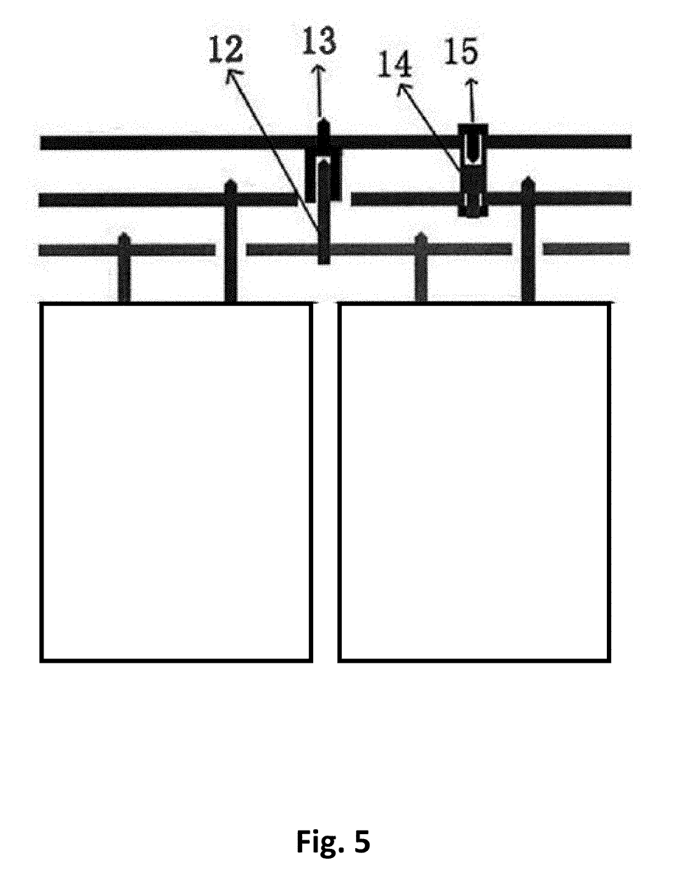

In a further embodiment of the present disclosure, since the capacitor also need internal charging, internal discharge loop and voltage detection feedback loop, using PCB board as a PCB bus plate so that a variety of electronic devices and interfaces can be easily added. As shown in FIG. 5, interfaces for connecting the PCB control board 9 are designed on the positive PCB bus plate 6 and the negative PCB bus plate 7, and then the interfaces are connected by means of a male row 12 and a female row 13 or by means of a screw barrel 14 and a screw 15, a very short installation distance between the PCB control board 9, the positive PCB bus plate 6 and the negative PCB bus plate 7 can be achieved. In this way, an ultra-compact structure of a capacitive power supply for welding equipment can be obtained, and making the whole structure extremely compact without excess cable and wiring row.

In a further embodiment of the present disclosure, for maintaining the insulation distance between the PCB bus plates, plastic isolation columns can be provided to enhance the insulation effect. The plastic isolation column is arranged between the positive PCB bus plate 6 and the negative PCB bus plate 7, and a plurality of plastic isolation columns may be provided as necessary for improve the insulation effect. The plastic isolation columns provided in the present embodiment not only serves as an insulation but also increases the anti-compression ability of the positive PCB bus plate 6 and the negative PCB bus plate 7 so that the insulation distance will not be easily shortened under a pressure.

In a further embodiment of the present disclosure, the stacked output structure of the present disclosure includes an MOSFET electronic switching device integrated on a PCB bus plate and a corresponding MOSFET drive circuit on the PCB bus plate. As shown in Fig.4, a drive signal input port 10 is provided at the lower end of the positive PCB bus plate 6, and the positive PCB bus plate 6 is arranged with a plurality of MOSFET electronic switching devices 11, a copper foil cabling on the positive PCB bus plate 6 keeps the MOSFET drive circuit insulated from a power output circuit. This embodiment features that the integrated MOSFET drive circuit can simultaneously drive more than one MOSFET. As an electronic switching device, MOSFET has the advantages of small size, small conduction voltage drop, small conduction resistance, simple drive circuit and low energy consumption. With the evolution of semiconductor technology, high-power POWER MOSFET has a very strong instantaneous current resistance, and after the actual verification, the use of multiple MOSFETs to replace the large-scale SCR of the prior art effectively reduce the volume and cost. Stacked structure power buses made of metal foils in the prior art cannot integrate various electronic devices (especially electronic switching devices) on the power buses. According to an embodiment of the present disclosure, an IGBT can also be used as an electronic switching device.

In a further embodiment of the present disclosure, since the capacitor also need internal charging, internal discharge loop and voltage detection feedback loop, using PCB board as a PCB bus plate so that a variety of electronic devices and interfaces can be easily added. As shown in FIG. 5, interfaces for connecting the PCB control board 9 are designed on the positive PCB bus plate 6 and the negative PCB bus plate 7, and then the interfaces are connected by means of a male row 12 and a female row 13 or by means of a screw barrel 14 and a screw 15, a very short installation distance between the PCB control board 9, the positive PCB bus plate 6 and the negative PCB bus plate 7 can be achieved. In this way, an ultra-compact structure of a capacitive power supply for welding equipment can be obtained, and making the whole structure extremely compact without excess cable and wiring row.

In a further embodiment of the present disclosure, for maintaining the insulation distance between the PCB bus plates, plastic isolation columns can be provided to enhance the insulation effect. The plastic isolation column is arranged between the positive PCB bus plate 6 and the negative PCB bus plate 7, and a plurality of plastic isolation columns may be provided as necessary for improve the insulation effect. The plastic isolation columns provided in the present embodiment not only serves as an insulation but also increases the anti-compression ability of the positive PCB bus plate 6 and the negative PCB bus plate 7 so that the insulation distance will not be easily shortened under a pressure.

Compared with the prior art, the stacked output structure of the capacitive power supply provided by the present disclosure can greatly improve the total surface area of conductive bus layers and reduce the inductive reactance and impedance upon current converge and output. Meanwhile, with the stacked structure, the positive PCB bus plate 6 and the negative PCB bus plate 7 can be directly led out in the same direction without having to provide a copper bar for bridging or leading out cables, and the impedance is further reduced. The stacked structure is simple to assemble, occupies little space, facilitates installing of other plate-shaped accessories, such as the control board, etc. By adopting the stacked output structure of the capacitive power supply according to the present disclosure, the impedance and inductive reactance can be greatly reduced when outputting power, and improve the output ratio of the capacitive power supply. Meanwhile, the stacked output structure allows a more flexible arrangement and can be conveniently connected with other components, such as the control board, etc. Thus, the stacked output structure is practical and convenient and has great market competitiveness.

While some embodiments of the present disclosure have been described in detail through above specific structure and size data, the invention is not limited to thereto. Various equivalent variations or substitutions may be made by the skilled in the art without departing from the scope of the disclosure, and are all included within the scope the disclosure defined by the appended claims.

1. A stacked output structure of a capacitive power supply for welding equipment, comprising:
a plurality of capacitors to be connected in parallel, two electrodes of each capacitor are respectively provided with a pin, wherein:
the two pins of each of the capacitors includes a long pin and a short pin, a group of pins with the same height being provided with the same polarity;
at least two PCB bus plates placed in stack provided above the capacitor, wherein:
a lower PCB bus plate is connected with the short pin; and a passing through hole is provided, at a position corresponds to the long pin, on the lower PCB bus plate; and
the long pin passes through the passing through hole in the lower PCB bus plate and is connected with an upper PCB bus plate; and there is a gap between the long pin and an inner wall of the passing through hole.

2. The stacked output structure of the capacitive power supply for welding equipment according to claim 1, wherein a conductive bus layer is provided on a surface of a PCB bus plate.

3. The stacked output structure of the capacitive power supply for welding equipment according to claim 2, wherein at least one conductive bus layer is provided within a PCB bus plate.

4. The stacked output structure of the capacitive power supply for welding equipment according to claim 2, wherein bus layers on the same PCB bus plate are provided for the same polarity; and the pins are connected with the bus layers of the PCB bus plate.

5. The stacked output structure of the capacitive power supply for welding equipment according to claim 2, wherein an insulation layer for protecting a bus layer is provided on a surface of the PCB bus plate.

6. The stacked output structure of the capacitive power supply for welding equipment according to claim 3, wherein an insulation layer for separating each bus layer is provided within the PCB bus plate.

7. The stacked output structure of the capacitive power supply for welding equipment according to claim 1, wherein a PCB control board is provided above the stack of PCB bus plates; and pins for power terminals of the PCB control board are respectively connected with the PCB bus plates with different polarities.

8. The stacked output structure of the capacitive power supply for welding equipment according to claim 1, wherein two electrodes of each capacitor are respectively provided with a pin upwards.

9. The stacked output structure of the capacitive power supply for welding equipment according to claim 1, wherein a conductive bus layer is provided on each of two surfaces of a PCB bus plate.

10. The stacked output structure of the capacitive power supply for welding equipment according to claim 3, wherein bus layers on the same PCB bus plate are provided for the same polarity; and the pins are connected with the bus layers of the PCB bus plate.

11. A stacked output structure of the capacitive power supply for welding equipment, comprising a plurality of capacitors to be connected in parallel, and two electrodes of each capacitor are respectively provided with a pin, wherein:
the two pins of each of the capacitors includes a long pin and a short pin, a group of pins with the same height being provided with the same polarity;
a PCB bus plate is provided above the capacitor; at least two bus layers are provided on and/or within the PCB bus plate; and the bus layers are separated by an insulation layer;
a plurality of hole slots leading to respective bus layers are formed on one side of the PCB bus plate facing the capacitors; and
the short pin of each capacitor is connected with a lower bus layer by means of a hole slot; and the long pin of each capacitor is connected with an upper bus layer by means of a hole slot.

12. The stacked output structure of the capacitive power supply for welding equipment according to claim 11, wherein two electrodes of each capacitor are respectively provided with a pin upwards.
